(19) United States
(12) Patent Application Publication
(10) Pub. No.: US 2013/0029476 A1
(43) Pub. Date: Jan. 31, 2013

(54) DICING PROCESS AND DICING APPARATUS

(71) Applicants: Chien-Sen WENG, Zhubei (TW); Mong-Yeng Xing, Miaoli County (TW); Yu-Ching Chang, Miaoli County (TW); Wei-Chang Yu, Kaohsiung City (TW); Yao-Hui Lin, Taipei City (TW)

(72) Inventors: Chien-Sen WENG, Zhubei (TW); Mong-Yeng Xing, Miaoli County (TW); Yu-Ching Chang, Miaoli County (TW); Wei-Chang Yu, Kaohsiung City (TW); Yao-Hui Lin, Taipei City (TW)

(73) Assignee: LEXTAR ELECTRONICS CORP., Hsinchu (TW)

(21) Appl. No.: 13/540,781

(22) Filed: Jul. 3, 2012

(30) Foreign Application Priority Data
Jul. 27, 2011 (TW) 100126608

(51) Int. Cl. H01L 21/78

(52) U.S. Cl. 438/462; 29/25.01; 257/E21.599

(57) ABSTRACT

A dicing process is provided for cutting a wafer along a plurality of predetermined scribe lines into a plurality of dies that are releasably adhered to a release film. The dicing process includes: (a) disposing a wafer-breaking carrier on a supporting device, the wafer-breaking carrier having a chipping unit; (b) disposing the wafer above the supporting device such that the chipping unit is at a position corresponding to the scribe lines; and (c) adhering a release surface of the release film to the wafer by applying a force to the release film to contact the chipping unit of the wafer-breaking carrier with the wafer, such that the wafer is split along the scribe lines into the dies.

### CROSS-REFERENCE TO RELATED APPLICATION

This application claims priority of Taiwanese application no. 100126608, filed on Jul. 27, 2011.

### BACKGROUND OF THE INVENTION

1. Field of the Invention

The present invention relates to a dicing process and a dicing apparatus, more particularly to a dicing process which can accomplish attachment of a release film on die units of a wafer and simultaneous separation of the die units, and a dicing apparatus for performing the same.

2. Description of the Related Art

Referring to FIGS. 1 and 2, a conventional dicing process comprises in sequence a wafer adhering step 111, a wafer positioning and dicing step 112, and a repeating step 113. By the conventional dicing process, a wafer 12 with a plurality of predetermined scribe lines 121 is split into a plurality of dies that are spaced apart from each other so as to be packaged in a subsequent process.

More specifically, at first, in the wafer adhering step 111, a back side of a wafer 12 with a plurality of predetermined scribe lines 121 is adhered to a carrier film 13 by means of a film attaching device (not shown). The carrier film 13 has a releasable surface that is releasably adhered to the wafer 12. In the semiconductor field or photoelectric field, the carrier film 13 is usually one of a blue tape, a UV tape, and a thermal tape.

The wafer 12 that has been adhered to the carrier film 13 is disposed on a supporting device and a positioning program such as an image identification system equipped with a charge coupled device is used to automatically search and memorize the positions of the scribe lines 121 on the wafer 12. A split knife 14 is at a position corresponding to align with one of the scribe lines 121 to be split and the split knife 14 is struck by, for example, a vibration hammer 15, so that the split knife 14 is driven to abut against the corresponding scribe line 121 so as to split the wafer 12 along the scribe line 121.

Finally, in the repeating step 113, the split knife 14 is aligned in sequence with a respective one of the predetermined scribe lines 121 on the wafer 12 in a horizontal direction or a vertical direction and then strikes and splits the wafer 12. In this way, a plurality of die units that are defined by the predetermined scribe lines 121 on the wafer 12 can be completely split into a plurality of individually separated dies.

The conventional dicing process requires a large number of steps and more time for repeatedly performing the wafer positioning and dicing step 112 when the number of the die units to be split in a unit surface area of the wafer 12 is increased, thereby lowering the manufacturing efficiency. In addition, since the wafer positioning and dicing step 112 and the repeating step 113 must be performed by sequentially moving the split knife 14 to the positions corresponding to the scribe lines 121 and then dicing the same, if either an error occurs in the coordination memorized by the image identification system or the split knife 14 can not be positioned accurately, the wafer 12 will be damaged, thereby lowering the production yield.

### SUMMARY OF THE INVENTION

Therefore, the object of the present invention is to provide a dicing process that can simplify the process, enhance the efficiency of the dicing process, and improve the production yield.

Another object of the present invention is to provide a dicing apparatus that can simplify the dicing process, enhance the efficiency of the dicing process, and improve the production yield.

According to an aspect of the present invention, a dicing process is provided for cutting a wafer along a plurality of predetermined scribe lines into a plurality of dies that are releasably adhered to a release film. The dicing process comprises: (a) carrier installing step: disposing a wafer-breaking carrier on a supporting device, the wafer-breaking carrier having a chipping unit; (b) wafer positioning step: disposing the wafer above the supporting device such that the chipping unit is at a position corresponding to the scribe lines; and (c) adhering and dicing step: adhering a release surface of the release film to the wafer by applying a force to the release film to contact the chipping unit of the wafer-breaking carrier with the wafer, such that the wafer is split along the scribe lines into the dies that are spaced apart from each other and that are adhered to the release film.

According to another aspect of the present invention, a dicing apparatus is provided for cutting a wafer along a plurality of scribe lines formed on the wafer to obtain a plurality of dies that are spaced apart from each other and that are adhered to a release film. The dicing apparatus comprises: a supporting device for positioning the wafer thereon; a wafer-breaking carrier that is disposed on the supporting device, and that includes a chipping unit, the chipping unit of the wafer-braking carrier to be at a position corresponding to the scribe lines when the wafer is disposed above the supporting device; and a film attaching device that is configured to wind up the release film and adhere the release film to the wafer positioned above the supporting device, wherein, when adhering the release film to the wafer, a force is supplied to the wafer to abut the chipping unit of the wafer-breaking carrier against the wafer, and the wafer is split along the scribe lines into a plurality of dies that are spaced apart from each other and adhered to the release film.

### BRIEF DESCRIPTION OF THE DRAWINGS

Other features and advantages of the present invention will become apparent in the following detailed description of the preferred embodiments with reference to the accompanying drawings, of which:

FIG. 1 is a flowchart of a conventional dicing process;

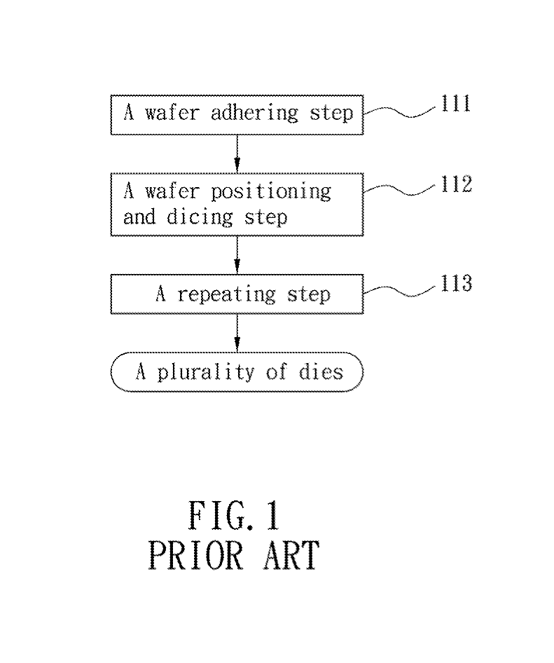

FIG. 2 is a fragmentary partly sectional view illustrating a dicing step of the conventional dicing process;

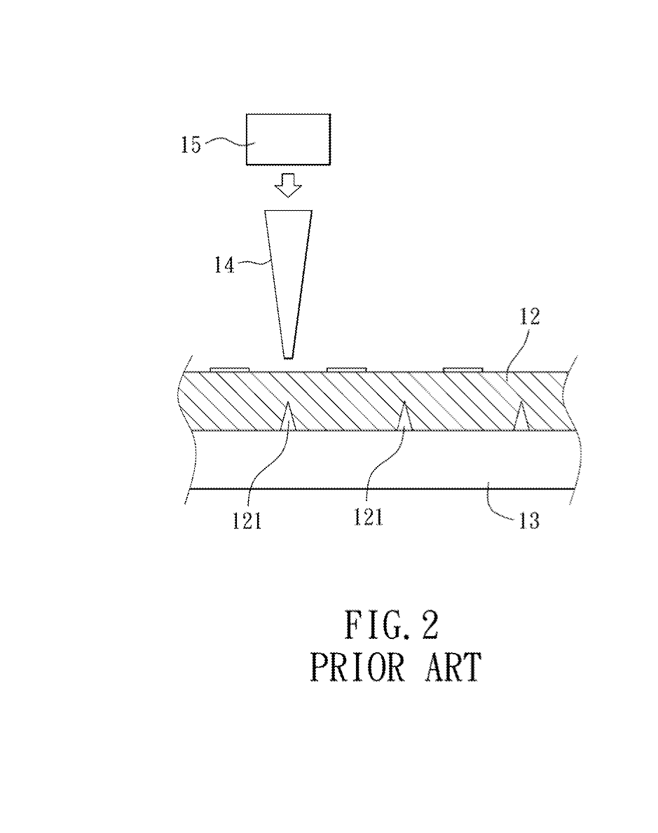

FIG. 3 is an exploded perspective view of the preferred embodiment of a dicing apparatus according to the present invention;

FIG. 4 is a fragmentary partly sectional view of the preferred embodiment of the dicing apparatus according to the present invention;

FIG. 5 is flowchart of the preferred embodiment of a dicing process according to the present invention; and

FIG. 6 is a perspective view illustrating a wafer-breaking carrier of another preferred embodiment of a dicing apparatus according to the present invention, the wafer-breaking carrier being equipped with a chipping unit.

### DETAILED DESCRIPTION OF THE PREFERRED EMBODIMENTS

Before the present invention is described in greater detail, it should be noted that like components are assigned the same reference numerals throughout the following disclosure.

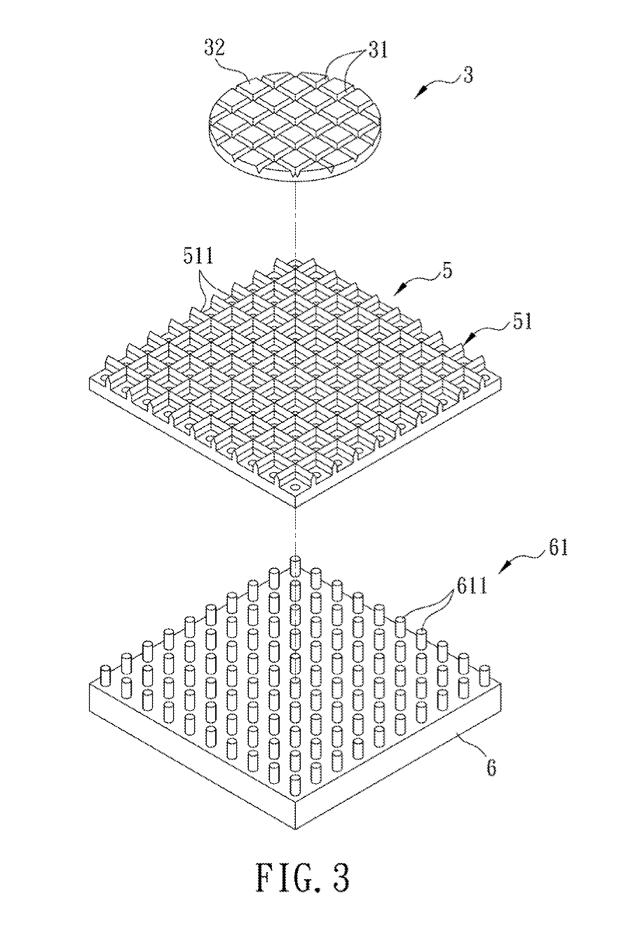

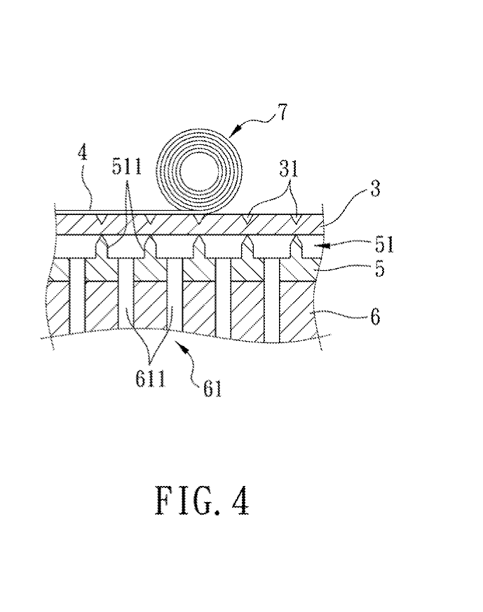

Referring to FIGS. 3 and 4, the preferred embodiment of a dicing apparatus of the present invention is adapted for cutting a wafer 3 that is formed with a plurality of scribe lines 31, and that includes a plurality of die units 32 defined by the scribe lines 31. The die units 32 are to be split into a plurality of dies that are adhered to a release film 4. The dicing apparatus comprises a wafer-breaking carrier 5, a supporting device 6, and a film attaching device 7.

The supporting device 5 is adapted for positioning the wafer 3 thereon. The supporting device 6 includes a wafer-attaching unit 61 that has a plurality of spaced apart suction nozzles 611. The suction nozzles 611 are controllable to switch between a vacuum state and a normal state by, for example, an external pump (not shown).

The wafer-breaking carrier 5 is disposed on the supporting device 6, and includes a chipping unit 51. In this embodiment, the chipping unit 51 includes a plurality of longitudinal and transverse intersecting ribs 511 each of which has a sharp upper edge. The sharp upper edges of the ribs 511 of the chipping unit 51 are at positions corresponding to the scribe lines 31 when the wafer 3 is disposed above the supporting device 6.

The film attaching device 7 winds up the release film 4 and is used to controllably adhere the release film 4 to the wafer 3 positioned above the supporting device 6. When adhering the release film 4 to the wafer 3, a force is supplied to the wafer 3 to abut the chipping unit 51 of the wafer-breaking carrier 5 against the wafer 3. The wafer 3 is then split along the scribe lines 31 into a plurality of dies that are spaced apart from each other and adhered to the release film 4.

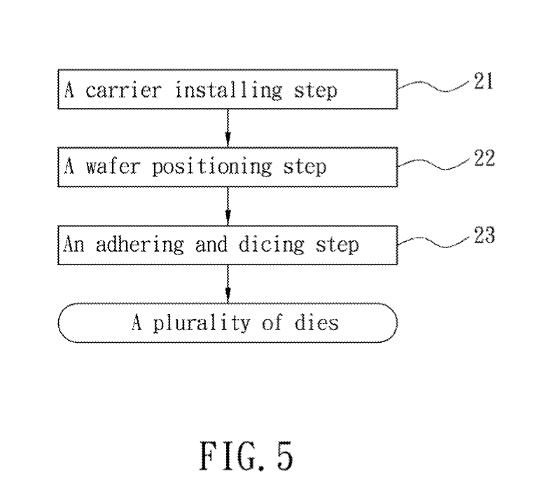

Next, the preferred embodiment of a dicing process according to the present invention will be described with reference to FIG. 5.

As shown in FIG. 5, the dicing process comprises a carrier installing step 21, a wafer positioning step 22, and an adhering and dicing step 23. With further reference to FIG. 4, the dicing process is adapted for cutting a wafer 3 along a plurality of predetermined scribe lines 31 into a plurality of dies that are releasably adhered to a release film 4. In addition, the scribe lines 31 may be formed on a surface of the wafer 3 by using a laser cutting process, a photolithography process, or a knife wheel cutting process that are well known in the art and will not be described herein.

At first, in the carrier installing step 21, the wafer-breaking carrier 5 having the chipping unit 51 is separable disposed on the supporting device 6 so that the suction nozzles 611 of the wafer-attaching unit 61 extend through the wafer-breaking carrier 5 among the plurality of longitudinal and transverse intersecting ribs 511.

Next, in the wafer positioning step 22, the wafer 3 is disposed above the supporting device 6 such that the chipping unit 51 is at a position corresponding to the scribe lines 31. At this time, the suction nozzles 611 of the wafer-attaching unit 61 are controlled to switch from the normal state to the vacuum state so as to respectively suck the die units 32 (see FIG. 3) formed on the wafer 3.

Finally, in the adhering and dicing step 23, in this embodiment, a release surface of the release film 4 is adhered to the wafer 3 by applying a force to the release film 4 using a roller of the film attaching device 7. The roller winds up the release film 4. At this time, by virtue of the force applied from the roller of the film attaching device 7, the sharp upper edges of the ribs 511 of the chipping unit 51 contact the wafer 3, such that the wafer 3 is split along the scribe lines 31 into the dies that are spaced apart from each other and that are adhered to the release film 4. After the adhering and dicing step 23, the suction nozzles 611 are controlled to switch from the vacuum state to the normal state so as to obtain the dies.

Although, in the adhering and dicing step 23, the release film 4 is pressed against the wafer 3 by the roller as shown in FIG. 4, other techniques, for example, flat panel pressing technique, and clamping technique or the like that are well known in the art may be used to attach the release film 4 to the wafer 3 and simultaneously split the wafer 3 along the scribe lines 31 into the dies.

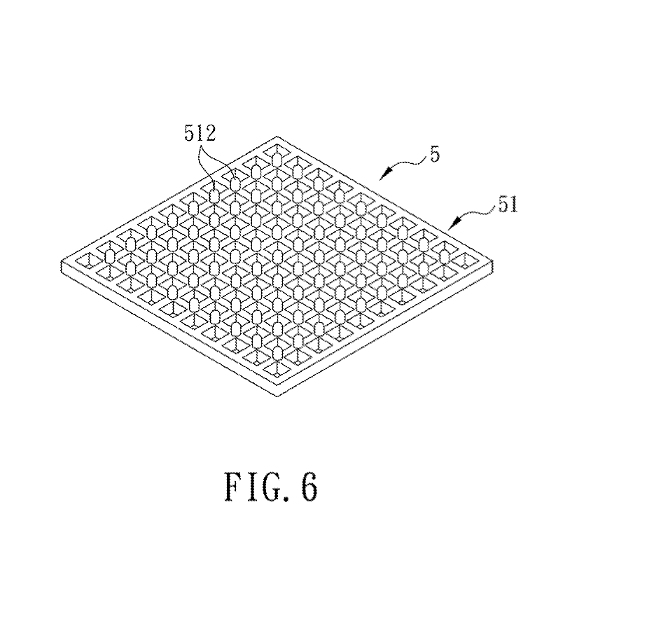

It should be noted that the chipping unit 51 of the wafer-breaking carrier 5 is not limited to the structure as described in the aforesaid preferred embodiment, but may be varied based on the actual process implementation. For example, as shown in FIG. 6, the chipping unit 51 of the wafer-breaking carrier 5 includes a plurality of protrusions 512 which are arranged spaced apart equidistantly and which are at positions corresponding to intersections of the scribe lines 31 (see FIG. 3). When the force is applied to the release film 4 to contact the chipping unit 51 of the wafer-breaking carrier 5 with the wafer 3, the wafer 3 is split from the intersections of the scribe lines 31 along the scribe lines 31 so as to obtain the plurality of dies.

To sum up, in this invention, by virtue of the force applied to the wafer 3 when attaching the release film 7 to the wafer 3, the wafer 3 can be adhered to the release film 7 and simultaneously split, such that time consuming problem and poor alignment accuracy encountered in the conventional dicing process can be greatly improved, thereby enhancing process efficiency and reducing the yield loss upon separation of the die units 32.

While the present invention has been described in connection with what are considered the most practical and preferred embodiments, it is understood that this invention is not limited to the disclosed embodiments but is intended to cover various arrangements included within the spirit and scope of the broadest interpretation so as to encompass all such modifications and equivalent arrangements.

What is claimed is:

1. A dicing process for cutting a wafer along a plurality of predetermined scribe lines into a plurality of dies that are releasably adhered to a release film, the dicing process comprising:
(a) carrier installing step: disposing a wafer-breaking carrier on a supporting device, the wafer-breaking carrier having a chipping unit;
(b) wafer positioning step: disposing the wafer above the supporting device such that the chipping unit is at a position corresponding to the scribe lines; and
(c) adhering and dicing step: adhering a release surface of the release film to the wafer by applying a force to the release film to contact the chipping unit of the wafer-breaking carrier with the wafer, such that the wafer is split along the scribe lines into the dies that are spaced apart from each other and that are adhered to the release film.

2. The dicing process of claim 1, wherein the chipping unit includes a plurality of longitudinal and transverse intersecting ribs, and in step (c), the intersecting ribs are at positions corresponding to the scribe lines and abut against the wafer.

3. The dicing process of claim 1, wherein the chipping unit includes a plurality of spaced apart protrusions, and in step (c), the protrusions are at positions corresponding to intersections of the scribe lines and abut against the wafer.

4. The dicing process of claim 1, wherein the supporting device includes a wafer-attaching unit for fixing the wafer, the wafer-attaching unit having a plurality of suction nozzles that are controllable to switch between a vacuum state and a normal state, the suction nozzles being controlled in the vacuum state during steps (b) and (c) to respectively suck the wafer, the suction nozzles being controlled in the normal state after the step (c) to obtain the dies that are spaced apart from each other and adhered to the release film.

5. The dicing process of claim 1, wherein the step (c) includes: roller-pressing the release film against the wafer using a film attaching device.

6. A dicing apparatus for chipping a wafer along a plurality of scribe lines formed on the wafer to obtain a plurality of dies that are spaced apart from each other and that are adhered to a release film, the dicing apparatus comprising:
a supporting device for positioning the wafer thereon;
a wafer-breaking carrier that is disposed on said supporting device, and that includes a chipping unit, said chipping unit of said wafer-braking carrier to be at a position corresponding to the scribe lines when the wafer is disposed above said supporting device; and
a film attaching device that is configured to wind up and adhere the release film to the wafer positioned above said supporting device, wherein, when adhering the release film to the wafer, a force is supplied to the wafer to abut the chipping unit of the wafer-breaking carrier against the wafer, and the wafer is split along the scribe lines into a plurality of dies that are spaced apart from each other and adhered to the release film.

7. The dicing apparatus of claim 6, wherein said chipping unit includes a plurality of longitudinal and transverse intersecting ribs.

8. The dicing apparatus of claim 6, wherein said chipping unit includes a plurality of protrusions that are arranged spaced apart equidistantly.

9. The dicing apparatus of claim 6, wherein said supporting device includes a wafer-attaching unit that has a plurality of spaced apart suction nozzles.

10. The dicing apparatus of claim 9, wherein said suction nozzles are controllable to switch between a vacuum state and a normal state, and when the wafer formed with the scribe lines is positioned above said supporting device, said suction nozzles are controlled in the vacuum state to respectively suck the wafer.
